(19) United States
(12) Patent Application Publication
(10) Pub. No.: US 2015/0034156 A1
(43) Pub. Date: Feb. 5, 2015

(54) RADIATION CURABLE ADHESIVE COMPOSITION FOR PHOTOVOLTAIC BACKSHEETS

(71) Applicants: Arkema Inc., King of Prussia, PA (US); Arkema France, Colombes (FR)

(72) Inventors: Robert L. Kensicki, Downingtown, PA (US); Joshua M. Oliver, Devon, PA (US); Amy A. Lefebvre, Pottstown, PA (US); Gregory S. O'Brien, Downingtown, PA (US)

(21) Appl. No.: 14/377,905

(22) PCT Filed: Feb. 14, 2013
(86) PCT No.: PCT/US2013/026018

§ 371 Date: Aug. 11, 2014

Related U.S. Application Data
(60) Provisional application No. 61/599,656, filed on Feb. 16, 2012.

(51) Int. Cl. C09J 175/14; B32B 27/32; B32B 38/00; H01L 31/048; B32B 37/16; B32B 37/12; B32B 27/08; B32B 7/12

(52) U.S. Cl. CPC C09J 175/14; B32B 27/08; B32B 27/322; B32B 7/12; H01L 31/0487; B32B 37/16; B32B 37/12; B32B 38/0008; B32B 2307/41; B32B 2327/12; B32B 2367/00; B32B 2457/12; B32B 2037/1253; B32B 2310/0831
USPC 136/256; 428/421; 428/412; 428/422; 428/414; 156/275.5

(57) ABSTRACT

The invention relates to a radiation curable adhesive system for use in bonding a high thermal deformation temperature layer to a UV opaque, pigmented or non-pigmented fluoropolymer film The radiation curable adhesive system uses an adhesive composition optimized for cure using long wavelength UV energy. The adhesive system may also be optimized for curing by LED or e-beam radiation. The system is designed for curing through a UV opaque fluoropolymer film—and especially where titanium dioxide is used as the pigment. A preferred multilayer film structure is a polyvinylidene fluoride (PVDF)/curable adhesive/polyester terephthalate (PET) structure. This film structure is especially useful as a backsheet for a photovoltaic module.

### FIELD OF THE INVENTION

The invention relates to a radiation curable adhesive system for use in bonding a high thermal deformation temperature layer to a UV opaque, pigmented or non-pigmented fluoropolymer film. The radiation curable adhesive system uses an adhesive composition optimized for cure using long wavelength UV energy. The adhesive system may also be optimized for curing by LED or e-beam radiation. The system is designed for curing through a UV opaque fluoropolymer film—and especially where titanium dioxide is used as the pigment. A preferred multilayer film structure is a polyvinylidene fluoride (PVDF)/curable adhesive/polyester terephthalate (PET) structure. This film structure is especially useful as a backsheet for a photovoltaic module.

### BACKGROUND OF THE INVENTION

Photovoltaic (PV) modules typically consist of a transparent glass or polymer frontsheet, solar cells protected by encapsulation, and a backsheet. The solar cells could be made of materials known in the art for this use, including, but not limited to: crystalline silicon, amorphous silicon, cadmium indium gallium selenide (CIGS), or cadmium indium selenide (CIS), organic polymer molecules, small organic molecules, or other similar materials. The backsheet is exposed to the environment on the backside of the module. The primary function of the backsheet is to provide protection to the encapsulated cells from degradation induced by reactions with water, oxygen, and/or UV radiation. The backsheet also provides electrical insulation for the module. Solar cells are commonly encapsulated in ethylene vinyl acetate (EVA), so the backsheet material should adhere well to EVA when the components of the PV are laminated together in a thermoforming process. Other useful encapsulants include, but are not limited to, ethyl vinyl acetate, a polyolefin, a functional polyolefin, an ionomer, a silicone, a grafted polyolefin-polyamide copolymer, and polyvinyl butryl.

The PV backsheet is typically a multi-layer film structure, consisting of a high thermal deformation temperature layer, such as a polyester, or similar film layer, having one or more thin layers of fluoropolymer on the outer side—being exposed to the environment on the side of the PV module facing away from direct solar radiation. Generally, at least one fluoropolymer outer layer is pigmented or UV opaque—normally containing one or more white pigments. The high thermal deformation temperature layer typically has either another fluoropolymer film, or a polyolefin layer on the side facing the interior of the module. The fluoropolymer film(s) are adhered to the high thermal deformation temperature layer with an adhesive.

The adhesive is typically a two-part copolyester, urethane, or acrylic solvent based adhesive. These adhesives must provide good bond strength to both the fluoropolymer film and polyester film, as well as have high heat and chemical resistance, and must further be non-yellowing with environmental exposure. While these adhesive systems are useful in PV module construction, they have some drawbacks. In particular, these adhesive systems can require one to two weeks to fully cure at room temperature. Thus backsheet producers must account for this long cure time in their production cycle to ensure sufficient cure. In addition, these solvent based adhesive systems contain volatile organic compounds that have to be handled in an appropriate manner by the backsheet manufacturer.

UV curable adhesives are known to cure at much faster rates than standard two-part solvent based adhesives, so it would be advantageous to find a suitable UV curable adhesive system for the production of PV backsheets. Unfortunately, titanium dioxide (TiO₂) white pigment that is commonly used in the pigmented fluoropolymer film, is known to absorb 100% of the photons under 400 nm and over 80% of the photons between 400-500 nm. This creates a major problem when using UV initiated free radical polymerization as a method of cure with titanium dioxide dispersed in a coating or in a film.

Surprisingly, a radiation curable adhesive system has been developed that can be used to adhere UV blocking fluoropolymer films to polyester films. This adhesive system cures rapidly through either the UV blocking fluoropolymer film or the high thermal deformation temperature layer and has been demonstrated to have very good bond strength to both fluoropolymer films and polyester films. The adhesive composition also has excellent heat and humidity resistance. The adhered multi-layer films are useful as backsheet structures in a photovoltaic module.

### SUMMARY OF THE INVENTION

The invention relates to a multi-layer film structure having, in order:

a multi-layer structure comprising, in order:

a) a high thermal deformation temperature layer;

b) an adhesive composition layer cured fully or partially by UV, LED or e-beam radiation;

c) a UV opaque fluoropolymer film layer;

wherein the layers are adjacent to each other.

The invention further relates to a method for forming the multilayer film structure making up the steps of:

a) forming a radiation curable adhesive composition comprising:
1) an adhesive comprising an aliphatic urethane acrylate oligomer, and one or more (meth)acrylate monomers; and aromatic oligomers, and
2) a photoinitiator;

b) applying said adhesive composition between a high thermal deformation temperature layer and at least one pigmented fluoropolymer layer;

c) combining together said high thermal deformation temperature layer, at least one pigmented fluoropolymer layer, and said adhesive to form a multi-layer structure;

d) exposing said coated and laminated multilayer structure to long UV (>400 nm)

wavelength radiation, to produce a cured adhesive layer directly bonding said high thermal deformation temperature layer to said fluoropolymer film(s).

### DETAILED DESCRIPTION OF THE INVENTION

All percentages used herein are weight percentages unless stated otherwise, and all molecular weights are weight average molecular weights unless stated otherwise. All references cited are incorporated herein by reference.

The multi-layer structure of the invention is formed of a high thermal deformation temperature layer adhered to one or more UV opaque fluoropolymer film layer(s) by one or more radiation-cured adhesive layer(s).

### Fluoropolymer Film

The fluoropolymer film of the invention is on the outermost back surface of the multi-layer structure—exposed to the environment on the side of the structure away from direct solar exposure. The fluoropolymer film may be a single layer, or may be a multi-layer structure. In a multi-layer fluoropolymer film, the outermost layer contains fluoropolymer, though inner layers may or may not contain fluoropolymer. Fluoropolymers useful in the invention include, but are not limited to polyvinylidene fluoride (PVDF), ethylene tetrafluoroethylene (ETFE), terpolymers of ethylene with tetrafluoroethylene and hexafluoropropylene (EFEP), terpolymers of tetrafluoroethylene-hexafluoropropylene-vinyl fluoride (THV), and blends of PVDF with polymethyl methacrylate polymers and copolymers. The fluoropolymers may be functionalized or unfunctionalized, and could be homopolymers or copolymers, and blends thereof. Other useful fluoropolymers include, but are not limited to ethylene chlorotrifluoroethylene (ECTFE) and polyvinyl fluoride (PVF).

In a preferred embodiment the fluoropolymer is polyvinylidene homopolymer, copolymer, terpolymer, or a blend of a PVDF homopolymer or copolymer with one or more other polymers that are compatible with the PVDF (co)polymer. PVDF copolymers and terpolymers of the invention are those in which vinylidene fluoride units comprise greater than 70 percent of the total weight of all the monomer units in the polymer, and more preferably, comprise greater than 75 percent of the total weight of the units. Copolymers, terpolymers and higher polymers of vinylidene fluoride may be made by reacting vinylidene fluoride with one or more monomers from the group consisting of vinyl fluoride, trifluoroethene, tetrafluoroethene, one or more of partly or fully fluorinated alpha-olefins such as 3,3,3-trifluoro-1-propene, 1,2,3,3,3-pentafluoropropene, 3,3,3,4,4-pentafluoro-1-butene, and hexafluoropropene, the partly fluorinated olefin hexafluoroisobutylene, perfluorinated vinyl ethers, such as perfluoromethyl vinyl ether, perfluoroethyl vinyl ether, perfluoro-n-propyl vinyl ether, and perfluoro-2-propoxypropyl vinyl ether, fluorinated dioxoles, such as perfluoro(1,3-dioxole) and perfluoro(2,2-dimethyl-1,3-dioxole), allylic, partly fluorinated allylic, or fluorinated allylic monomers, such as 2-hydroxyethyl allyl ether or 3-allyloxypropanediol, and ethene or propene. Preferred copolymers or terpolymers are formed with vinyl fluoride, trifluoroethene, tetrafluoroethene (TFE), and hexafluoropropene (HFP).

Especially preferred copolymers contain VDF comprising from about 71 to about 99 weight percent VDF, and correspondingly from about 1 to 29 percent HFP percent VDF, and correspondingly from about 1 to about 29 percent TFE; from (such as disclosed in U.S. Pat. No. 3,178,399); and from about 71 to 99 weight percent VDF, and correspondingly from about 1 to 29 weight percent trifluoroethylene.

Especially preferred thermoplastic terpolymers are the terpolymer of VDF, HFP and TFE, and the terpolymer of VDF, trifluoroethene, and TFE. The especially preferred terpolymers have at least 71 weight percent VDF, and the other comonomers may be present in varying portions, but together they comprise up to 29 weight percent of the terpolymer. In one preferred embodiment, the fluoropolymer is fluorosurfactant free, meaning that no fluoropolymer is used in the synthesis or further processing of the fluoropolymer.

The PVDF layer(s) could also be a blend of a PVDF polymer with a compatible polymer, such as polymethyl methacrylate (PMMA) and PMMA copolymers containing MMA monomer units and up to 35 wt % of C₁₋₄ alkyl acrylate co-monomer units, where the PVDF makes up greater than 30 weight percent, and preferably greater than 40 weight percent. PVDF and PMMA can be melt blended to form a homogeneous blend. In one embodiment at least one fluoropolymer layer is a blend of 60-80 weight percent of PVDF and 20-40 weight percent of polymethyl methacrylate or a polymethylmethacrylate copolymer.

Preferably, at least one layer of the fluoropolymer film is UV opaque. By “UV opaque” or “UV blocking”, as used herein is meant that the fluoropolymer contains additives that block at least 80%, and more preferably at least 90%, even more preferably at least 95% of the photons in the 300-380 nm range. This high photon blocking can be adjusted by changing the thickness of the film, the loading of the UV blocker(s), or both. While blocking the photons in the 300-400 nm range, the fluoropolymer film of the invention allows at least 10%, and preferably at least 15% of the photons in the 430-500 nm range to pass through the film. When curing in the invention is done using e-beam radiation, there is no limit to the amount of photon blocking in the fluoropolymer film at any wavelength.

In one embodiment, the UV blocker consists of one or more pigments, generally white pigments—which aid in reflectance of light. Pigments are generally present at levels of from 2.0 percent to 30 percent by weight, and preferably from 2.0 to 20 percent by weight, based on the polymer. Useful pigments include, but are not limited to titanium dioxide, zinc oxide, nano-zinc oxide, barium sulfate, and strontium oxide. The invention is also useful with other materials that contain other UV absorbing pigments—such as iron oxide, carbon black. Most of these pigments do not absorb radiation over the whole UV spectrum to the same level as titanium dioxide—and thus a photoinitiator package and UV radiation source can be tailored for maximum curing through materials containing those pigments.

In the case of titanium dioxide, which can be rutile or anatase, nearly all of the photons in the UV range are absorbed, all the way out to about 410 nm. Thus a special adhesive composition and photon source are required for proper curing through the UV opaque layer.

The adhesive system of the invention could also be applied to non-pigmented fluoropolymer films containing UV absorbers or inorganic nanopigments. Useful UV absorbers include, but are not limited to, hindered amine light stabilizers (HALS), 2-(o-hydroxyphenyl)benzotriazoles, nickel chelates, o-hydroxybenzophenones and phenyl salicylates. UV absorbers are present at from 0.05 to 5 weight percent, based on the total polymer weight in the UV opaque layer. The HALS can be monomeric or polymeric. Nanopigments, such as nano-zinc oxide and nano-cerium dioxide are pigments in the nanometer size range, allowing for a visibly transparent film that is UV blocking.

The fluoropolymer film surface may be surface treated or chemically primed to improve adhesion to the adhesive. For example, corona, plasma, or flame treatments could be used and/or chemical treatments like silane, urethane, acrylic, amine, or ethylene based primers could be applied to the film.

The PVDF film layer composition, in addition to PVDF and UV blocker(s), may contain other additives, such as, but not limited to impact modifiers, UV stabilizers, matting agents, plasticizers, fillers, coloring agents, antioxidants, antistatic agents, surfactants, toner, and dispersing aids.

The total fluoropolymer layer has a thickness of from greater than 1 micron to 125 microns, preferably from 5 to 75 microns, and most preferably from 5 to 50 microns.

### High Thermal Deformation Layer

The high thermal deformation layer provides structural support for the multi-layer film structure. By “high thermal deformation layer” as used herein is meant a thin layer of between 10 microns and 375 microns, and preferably between 12.5 and 250 microns, most preferably 12.5 and 125 microns, having a thermal deformation temperature greater than that used in a downstream manufacturing process involving the multi-layer film. Preferably the thermal deformation temperature is at least 10° C. and more preferably at least 15° C. above any manufacturing temperature. The thermal deformation temperature can be measured by DSC or DMA. For glassy polymers, the deformation temperature could be the Tg of the material. For crystalline polymers the deformation temperature could be the highest Tm in an alloy or graft copolymer. For testing by DMA the deformation temperature would be defined by a modulus as measured by DMA. For example, for a process where the highest downstream manufacturing temperature is 150° C., the DMA of the high thermal deformation layer would be greater than 75 MPa at 150° C., as measured by the DMA storage modulus.

Examples of materials useful in the high deformation temperature layer include, but are not limited to, polyesters, polyamides, polyethylene naphthalate (PEN), and polycarbonates. Useful polyamides include, but are not limited to polyamide 6 (PA6), PA 6,6, PA 11, PA 12, and polyamide alloys—such as ORAGOLLOY products (from Arkema Inc.). Useful polyesters include, but are not limited to polyethylene terephthalate (PET) and polybutylene terephthalate (PBT). An especially preferred high thermal deformation layer is PET.

The high deformation temperature layer may be treated or untreated. The treatment can be chemical—such as the application of a primer and/or a high energy surface pre-treatment, such as a corona, plasma, or flame treatment. For example, chemical treatments like silane, urethane, acrylic, polyethylenimine, or ethylene acrylic acid copolymer based primers could be applied to the substrate. The surface treatment or chemical primer may be the same or different on either side of the substrate depending upon the chemistry required to achieve good adhesion to the adhesives.

### UV Curable Adhesive

The UV opaque fluoropolymer film is adhered to the high thermal deformation temperature layer using a radiation curable adhesive composition. The adhesive composition includes a reactive oligomers, functional monomers, and photoinitiator (for use with photon radiation sources),

In a preferred embodiment, the adhesive composition contains one or more aliphatic urethane (meth)acrylates based on polyester and polycarbonate polyols, in combination with mono and multifunctional (meth)acrylate monomers. Alternately the oligomer can include mono or multifunctional (meth)acrylate oligomers having polyesters and/or epoxy backbones, or aromatic oligomers alone or in combination with other oligomers.

Non-reactive oligomers or polymers could also be used in conjunction with (meth)acrylate functional monomers and/or oligomers. The viscosity of the liquid adhesive composition can be adjusted by the choice of, and concentration of oligomers to monomers in the composition.

In a preferred embodiment, the adhesive composition contains only oligomers and monomers.

Monomers useful in the invention include, but are not limited to: (meth)acrylate esters of alcohols such as iso-octanol; n-octanol; 2-ethylhexanol, iso-decanol; n-decanol; lauryl alcohol; tridecyl alcohol; tetradecyl alcohol; cetyl alcohol; stearyl alcohol; behenyl alcohol; cyclohexyl alcohol; 3,3,5-trimethyl cyclohexyl alcohol; cyclic trimethylolpropane formal; 2-phenoxy ethanol; nonyl phenol, isobornol; and (meth)acrylate esters of diols and polyols such as ethylene glycol; propylene glycol; 1,3 propane diol; 1,3 butane diol; 1,4 butane diol; 1,6 hexanediol; 3-methyl-1,5-pentanediol; 1,9-nonanediol; 1,10-decanediol, 1,12-dodecanediol; 1,4-cyclohexanedimethanol; tricyclodecanedimethanol; neopentyl glycol; trimethylol propane; glycerol; tris(hydroxyethyl)isocyanurate; pentaerythritol; di-trimethylolpropane; di-pentaerythritol; and alkoxylated or caprolacatone modified derivatives of such alcohols,diols and polyols; dipropylene glycol; tripropylene glycol and higher polypropylene glycols; diethylene glycol; triethylene glycol; tetraethylene glycol and higher polyethylene glycols; mixed ethylene/propylene glycols. Dual functional monomers such as hydroxyl monomers such as hydroxyethyl acrylate or hydroxyl caprolactone acrylates may also be useful for adjustion system adhesion properties. Beta-carboxyethyl acrylate, a carboxyl functional acrylate monomer, is also useful in certain systems.

The use of 2(2-ethoxyethoxy) ethyl acrylate in a range of 1-15%, based on the total adhesive composition, increases peel strength in laminations having a PVDF film with an acrylate oligomer adhesive chemistry. Additionally the use of B-CEA (beta-carboxyethyl acrylate) has been shown to have a positive effect on the peel strength in these lamination structures.

Aliphatic urethane acrylate oligomers useful in the invention include, but are not limited to those prepared from aliphatic isocyanates such as; hydrogenated methylene diphenyldiisocyante; isophorone diisocyanate , hexamethylene diisocyanate, trimethyl hexamethylene diisocyanate and allophanates and biurets of such isocyanates in combination with various polydiols or polyols such as; polyester polyols derived from di or poly-hydroxy compounds and di or poly-carboxylic acid functional compounds., polyether diols derived from polyethylene glycol, polypropylene glycol, poly-1,3-propanediol, polybutanediol or mixtures of these; polycarbonate diols prepared from various diols such as 1.3-propanediol, 1,3-butanedio1,1,4-butanediol, 1,5-pentanediol, neopentyl glycol, methy pentanediol, 1,6-hexanediol, 1,4-cyclohexanediol, 2-ethyl hexyl diol and similar alkyl diols; end capped at both ends or one end with a hydroxyl functional (meth)acrylate capping agent such as hydroxyl ethyl (meth)acrylate, hydroxyl propyl (meth)acrylate, polycaprolactone(meth)acrylate.

Aliphatic urethane acrylates based off of polyester and polycarbonate polyols are preferred.

The aliphatic urethane acrylates generally have a molecular weight of from 500 to 20,000 daltons; more preferably between 1,000 and 10,000 daltons and most preferably from 1,000 to 5,000 daltons. If the MW of the oligomer is too great the cros slink density of the system is very low creating an adhesive that has a low tensile strength. Having too low of a tensile strength causes problems when testing peel strength as the adhesive may fail prematurely.

In another embodiment, the adhesive could be a UV curable cationic adhesive.

The content of aliphatic urethane oligomer in the oligomer/monomer blend should be 5% to 80% by weight; more preferably 10% to 60% by weight and most preferably from 20% to 50% by weight.

The cured adhesive layer is in the range of 0.5 to 1.5 mil, preferably from 0.75 to 1.25 mil in thickness. Thicker layers may not fully cure with a UV source, though this is not a limitation for e-beam. Thinner layer may not provide adequate adhesion.

### Photoinitiator

To polymerize or cure the adhesive composition using photons though a UV opaque fluoropolymer film, and especially through a white pigmented (TiO₂) film, the proper long wavelength UV or near visible light absorbing photoinitiator is required, in combination with a matching radiation source. The photoinitiator is one that absorbs photons to produce free radicals that will initiate a polymerization reaction. Useful photoinitiators of the invention include, but are not limited to bis acyl phosphine oxides (BAPO), and trimethyl-diphenyl-phosphineoxides (TPO), and blends thereof.

The photoinitiator is present in the adhesive composition at 0.2 to 2.0 weight percent based on the total of the adhesive composition, preferably from 0.5 to 1.0 percent by weight. In the alternative, if electron beam radiation is used for the curing, no photoinitiator is needed.

### Curing Method

The adhesive composition and radiation source is optimized for curing through a UV opaque fluoropolymer film.

For multi-layer constructions involving a PVDF film laminated to both sides of a PET, curing through the PVDF is the optimum method for processing. Long wavelength (meaning greater than 400 nm wavelength) UV energy is crucial to initiate the photoinitiator to decay into an initiating free radical species. One useful energy source to achieve the required spectral output is made by Fusion UV Systems. Fusion's 600 watt/inch gallium additive lamp more commonly known as a “V” lamp. The V lamp produces a high intensity spectral output of about 410 nm. The same adhesive performance and degree of cure could be achieved using a high power (600 watt/inch) gallium additive lamp from another lamp supplier, such as Nordson UV.

In one embodiment, a pigmented PVDF/PET/PVDF, with both PVDF films pigmented, an initial study evaluating peel strength vs. cure speed through the PET side showed that with the Fusion 600 watt/inch “V” lamp the maximum cure speed is 25 feet/minute before the peel strength drops off dramatically. With curing through the PVDF side, the peel strengths were lower overall, and it was determined that the optimal cure speed was only 20 feet/minute.

An alternative source of UV radiation for curing the adhesive system of the invention is a light emitting diode (LED), such as a Phoseon 415 nm LED. LED's differ from the traditional UV curing lamps in that they are nearly monochromatic compared to traditional UV curing lamps that emit a broad energy spectrum. Currently LED's are made in wavelengths ranging from 360-420 nm. Longer wavelength LED's, such as the 415 nm or 420 nm, could be used in the invention.

The UV cure of the invention could be used as part of a duel-cure system involving both UV cure and a thermal cure. Since the laminate structure will see a 150° C. bake for 15 minutes when it is laminated to the photovoltaic module. A greater degree of cure could be achieved with the same basic formulation changing some of the acryalate monomers to their methacrylate analogue and the addition of a thermally decomposing peroxide. Methacrylate monomers and oligomers cure about 8 times slower than their acrylate counter parts through UV free radical polymerization due to the steric hinderance on the methyl group. Because of this methacrylates are more typically used in thermal cure applications with a peroxide. Further, the use of photo-latent primary and secondary amines could be used in conjunction with either UV or thermal free radical initiators to achieve polymerization.

An alternative method for the production of free radicals in the present invention, would be through the use of electron beam (e-beam) radiation. With e-beam curing, there is no need for a photoinitiator in the adhesive composition. The use of e-beam cure also eliminates any negative effects of UV radiation on the high deformation temperature layer.

The viscosity of the adhesive is controlled by adjusting the level of oligomer to monomers in the adhesive composition. The adhesive is preferably applied to the fluoropolymer and high thermal deformation layer in an in-line operation. The adhesive may be applied by means known in the art, including but not limited to spray-coat, roll-coat, brush-coat, gravure print, flexographic print, or inkjet application.

In one embodiment of the invention, the radiation-curable adhesive is applied as a liquid onto the PET layer, followed by lamination with the PVDF layer in a roll to roll process. Alternately, the adhesive could be applied to the PVDF layer, then laminated onto the PET layer. The layers with the adhesive applied are then placed in contact with each other, generally using some pressure and optionally low heat—though the process is designed to work at room temperature. The laminate is then exposed to one or more radiation sources—that may be the same or different, as previously discussed, preferably in-line, and preferably from one or more sources of UV radiation, LED radiation, or electron beam radiation. When a three-layer laminate film, such as a PVDF/PET/PVDF film is produced, the adhesive is preferably applied at each interface, and the radiation cure occurs on both sides of the film. In one embodiment, the process is done on a roll-to-roll system, in which the individual layers of each film come off of their rolls, and the fully cured laminate is rolled up at the end of the process.

In one embodiment, line speeds of 20/feet/minute were found to effectively produce a PVDF/PET/PVDF adhered laminate. The line speed can be increased by means known in the art, such as by increasing the number of radiation sources (such as UV lamps), or by increasing the concentration of the photoinitiator.

In one embodiment of the invention, the fluoropolymer layer(s) in said multi-layer structure are UV transparent to more than 20 percent of the photons from 300-400 nm. The same UV, LED, or e-beam curing is used. In this case, lower levels of photoinitiator may be used, and higher line speeds expected, since additional UV radiation will be available to initiate crosslinking.

In a further embodiment of the invention, the fluoropolymer is transparent to UV radiation, and a UV absorber (pigment, nanopigment, organic UV absorber) is placed in the adhesive or in the high thermal deformation temperature layer, to provide a UV opaque multilayer structure.

### EXAMPLES

### Example 1

Radiometer data was obtained using an EIT Power Puck II. The EIT Power Puck II reads total energy in Joules/cm² and peak irradiance watts/cm² in four different bandwidths in the UV region of the electromagnetic spectrum. EIT defines these regions as UVV from 395-445 nm, UVA from 320-390 nm, UVB from 280-320 nm, and UVC from 250-260 nm. The total energy of a Fusion 600 watt/inch “V” lamp at a line speed of 50 feet/minute was 1.252 J/cm2 (EIT Power Puck II radiometer). When the same measurements are taken with a layer of KYNAR pigmented PVDF film from Arkema Inc., over the radiometer lens with the same Fusion 600 watt/in “V” lamp at the same line speed of 50 feet/minute the total energy drops to 0.232 J/cm2. This result shows a decrease in energy of over 80% when attempting to cure a material through the KYNAR PVDF film. More specifically the UVV region drops from 0.699 J/cm2 in air to 0.115 J/cm2 when measured through the KYNAR film.

### Example 2

Using a piece of glass roughly 18 inches high by 12 inches wide (size can vary depending on intended size of lamination) as a base, 2 pieces of SCOTCH 232 tape were applied vertically, one each on the left and right sides of one face of the glass. The width of the tape applied controls the size of the intended lamination. The SCOTCH 232 tape is about 5 mils thick. On top of each piece of SCOTCH 232 tape a second layer of SCOTCH 232 tape was applied, giving a thickness of about 10 mils off the glass. The tape controls the adhesive thickness in conjunction with the laminate structure. Two pieces of 2 mil thick release liner (or one 4 mil layer) were applied in the space between the pieces of tape on the glass face, one on top of the other and taped down at the top. On top of the release liners a layer of PET (5 mil thick DuPont XST-6578) being used in the laminate structure was placed down with the adhesion treated side facing up and taped down at the top. Next a PVDF layer with the surface treated side facing down was taped down at the top of the glass. The surface of the PVDF film had been treated with an Enercon corona treater to obtain a surface energy >50 dyne cm. All the layers were in-between the SCOTCH 232 tape and did not overlap the tape, since if any of the film layers were overlapping the SCOTCH tape the film thickness would be off. Next, the PVDF layer was pulled back to expose the PET layer. A UV adhesive containing 46.00% CN966H90 (an aliphatic urethane acrylate oligomer from Sartomer), 11.00% SR484 (an acrylate monomer from Sartomer), 21.00% SR506 (an acrylate monomer from Sartomer), 16.75% CD9055 (an acrylate monomer from Sartomer), 4.5% SR256 (an acrylate monomer from Sartomer), 0.50% TPO (a photoinitiator), and 0.25% IRGACUR 819 (bis phosphine oxide photoinitiator) was applied horizontally across the PET at or near the top. The amount of adhesive was related to the lamination size. Once the adhesive was applied to the PET the PVDF was pulled back and laid on top of the PET. In this procedure, the only limiting factors to the size of the laminate structure are the roller size and the lamp size. A 10 inch wide marble roller was placed on the 2 pieces of SCOTCH 232 tape at the top and was rolled at a steady pace down the SCOTCH tape until reaching the bottom. To insure a constant film thickness, rolling was repeated two or three times. The bottom of the lamination was then taped to the glass to prevent it from blowing around when put through the curing unit. The lamination was cured through the PVDF film with a Fusion 600 w/in “V” lamp at 20 F/M. Once cured the laminate structure was cut into 1 inch wide strips for testing. Testing included 180 degree peel strength done on an Instron and damp heat testing done in an 85C/85% RH chamber. The average initial peel strength of several samples was 2.09 lbs. The samples survived for more than 12 weeks in damp heat testing without any loss of adhesion or tunneling.

### Example 3

An alternative method to initiate free radical polymerization using acrylate and (meth) acrylate monomers and oligomers is by electron beam radiation commonly referred to as (e-beam curing). Electron beam curing works by applying a high voltage to a tungsten filament that is inside a vacuum chamber. The tungsten filaments become super heated electrically to generate a cloud of electrons. The electrons are accelerated and pass through a foil window to penetrate the adhesive and initiate polymerization. As e-beam curing does not require a photoinitiator to absorb energy and decay to generate free radicals for polymerization the addition of bis acyl phosphine oxides (BAPO), and trimethyl-diphenyl-phosphineoxides (TPO), and blends thereof were not used.

Using a piece of glass roughly 18 inches high by 12 inches wide (size can vary depending on intended size of lamination) as a base, 2 pieces of SCOTCH 232 tape were applied vertically, one each on the left and right sides of one face of the glass. The width of the tape applied controls the size of the intended lamination. The SCOTCH 232 tape is about 5 mils thick. On top of each piece of SCOTCH 232 tape a second layer of SCOTCH 232 tape was applied, giving a thickness of about 10 mils off the glass. The tape controls the adhesive thickness in conjunction with the laminate structure. Two pieces of 2 mil thick release liner (or one 4 mil layer) were applied in the space between the pieces of tape on the glass face, one on top of the other and taped down at the top. On top of the release liners a layer of PET (5 mil thick DuPont XST-6578) used in the laminate structure was placed down with the adhesion treated side facing up and taped down at the top. Next a PVDF layer with the surface treated side facing down was taped down at the top of the glass. The surface of the PVDF film had been treated with an Enercon corona treater to obtain a surface energy >50 dyne cm. All the layers were in-between the SCOTCH 232 tape and did not overlap the tape, since if any of the film layers were overlapping the SCOTCH tape the film thickness would be off. Next, the PVDF layer was pulled back to expose the PET layer. An acrylate based adhesive containing 47.00% PRO12546 (an aliphatic urethane acrylate oligomer from Sartomer), 15.00% SR506, 17.00% CD9055, 11.00% SR256, and 10.00% SR420 (acrylate monomer from Sartomer) was applied horizontally across the PET at or near the top. The amount of adhesive was related to the lamination size. Once the adhesive was applied to the PET the PVDF was pulled back and laid on top of the PET. A 10 inch wide marble roller was placed on the 2 pieces of SCOTCH 232 tape at the top and was rolled at a steady pace down the SCOTCH tape until reaching the bottom. To insure a constant film thickness, rolling was repeated two or three times. At this point the uncured lamination was carefully removed from the glass and taped to the web at the top and bottom of the lamination so it was secured when it was put through the curing unit. Samples were cured using a high voltage electron beam curing unit manufactured by Energy Science's, Inc. (ESI). It was determined by the film density of the PVDF top layer that 150KV electron voltage was required to penetrate the adhesive. Using an electron voltage of 150KV and an equivalent line speed to give a dose of 5 megarads (Mrads) samples were cured through the PVDF layer.

The cured laminations structures were cut into 1 inch wide strips for testing, and tested for 180 degree peel strength on an Instron and damp heat testing in an 85C/85% RH chamber. Samples were tested for peel strength prior to being placed in the damp heat chamber along with intervals of 1, 3, and 6 weeks of damp heat exposure. Initial peel average strengths were 3 lbs. The sample maintained this level of peel strength out to 6 weeks of exposure without any decrease.

### Example 4

Using a Light Emitting Diode or LED to cure the adhesive through the PVDF film is an alternative method to initiate free radical polymerizating. Using a piece of glass roughly 6 inches tall by 5 inches wide (size can vary depending on width of LED) as a base, 2 pieces of SCOTCH 232 tape were applied vertically one each on the left and right sides of one face the glass. The width of the tape applied controls the size of the intended lamination. The SCOTCH 232 tape is about 5 mils thick. On top of each piece of SCOTCH 232 tape a second layer of SCOTCH 232 tape was applied, giving a thickness of about 10 mils off the glass. The tape controls the adhesive thickness in conjunction with the laminate structure. Two pieces of 2 mil thick release liner (or one 4 mil layer) were applied in the space between the pieces of tape on the glass face, one on top of the other and taped down at the top. On top of the release liners a layer of PET (5 mil thick DuPont XST-6578) used in the laminate structure was placed down with the adhesion treated side facing up and taped down at the top. Next a PVDF layer with the surface treated side facing down was taped down at the top of the glass. The surface of the PVDF film had been treated with an Enercon corona treater to obtain a surface energy >50 dyne cm. All the layers were in-between the SCOTCH 232 tape and did not overlap the tape, since if any of the film layers were overlapping the SCOTCH tape the film thickness would be off. Next, the PVDF layer was pulled back to expose the PET layer. A UV adhesive containing 46.00% CN9021, 11.00% SR484, 21.00% SR506, 16.75% CD9055, 4.5% SR256, 0.50% TPO, and 0.25% IRGACUR 819 is applied horizontally across the PET at or near the top. The amount of adhesive was related to the lamination size. Once the adhesive was applied to the PET the PVDF was pulled back and laid on top of the PET. A 10 inch wide marble roller was placed on the 2 pieces of SCOTCH 232 tape at the top and was rolled at a steady pace down the SCOTCH tape until reaching the bottom. To insure a constant film thickness, rolling was repeated two or three times. At this point the uncured lamination was carefully removed from the glass and taped to the web at the top and bottom of the lamination so it was secured when it was put through the curing unit. The lamination was cured through the PVDF film with a water cooled Phoseon Fireline™ LED model 125X20WC 415-8W@a line speed of 17 F/M. The lamination sample should be passed under the LED curing unit total of (3) times. It should be noted that the lamination height was adjusted to as close as possible to the LED curing unit. As the distance from the semiconductors on the LED to the material being cured increases the energy to cure decreases drastically. Once cured the laminate structure was cut into 1 inch wide strips for testing, and tested for 180 degree peel strength on an Instron and damp heat testing in an 85C/85% RH chamber. Initial peel strengths averaged 2.98 lbs. The peel strength values remained above the initial strength after 1000 hours of damp heat (85C/85% RH) exposure.

### Example 5

Using a piece of glass roughly 18 inches high by 12 inches wide (size can vary depending on intended size of lamination) as a base, 2 pieces of SCOTCH 232 tape were applied vertically, one each on the left and right sides of one face of the glass. The width of the tape applied controls the size of the intended lamination. The SCOTCH 232 tape is about 5 mils thick. On top of each piece of SCOTCH 232 tape a second layer of SCOTCH 232 tape was applied, giving a thickness of about 10 mils off the glass. The tape controls the adhesive thickness in conjunction with the laminate structure. One piece of 2 mil thick release liner was applied between the pieces of tape on the glass and taped down at the top. Next, a 2 mil thick clear PVDF layer with the surface treated side facing up was taped down at the top of the glass. On top of the clear PVDF, the PET being used in the laminate structure in (5 mil thick DuPont XST-6578) is placed down with the adhesion treated side facing down and taped down at the top. It is important to make sure that all the layers are in-between the SCOTCH 232 tape and do not overlap. All the layers were in-between the SCOTCH 232 tape and did not overlap the tape. At this point the PET layer was pulled back to expose the PVDF layer. A UV adhesive containing 47.00% PRO12546, 15.00% SR506, 16.75% CD9055, 10.50% SR256, 10.00% CD420, 0.50% TPO, and 0.25% IRGACUR 819 was applied horizontally across the PVDF at or near the top. Once the adhesive is applied to the PVDF, the PET was pulled back and laid on top of the PVDF. The amount of adhesive was related to the lamination size. Once the adhesive was applied to the PET the PVDF was pulled back and laid on top of the PET. A 10 inch wide marble roller was placed on the 2 pieces of SCOTCH 232 tape at the top and was rolled at a steady pace down the SCOTCH tape until reaching the bottom. To insure a constant film thickness, rolling was repeated two or three times.

At this point the uncured lamination was carefully removed from the glass and taped to the web at the top and bottom of the lamination so it was secured when it was put through the curing unit. The lamination was cured through the PET film with a Fusion 600 w/in “V” lamp at 20 F/M. Once cured the laminate structure was cut into 1 inch wide strips for testing for 180 degree peel strength done on an Instron and damp heat testing done in an 85C/85% RH chamber. Initial peel average strengths of this sample were 6.00 lbs. After three weeks of damp heat exposure, the 180 degree peel strength of the lamination was above 4lbs. This sample survived more than 39 weeks in damp heat testing without any loss of adhesion or tunneling.

1. A multi-layer structure comprising, in order:
a) a high thermal deformation temperature layer;
b) an adhesive composition layer cured fully or partially by UV, LED or e-beam radiation;
c) a UV opaque fluoropolymer film layer;
wherein the layers are adjacent to each other.

2. The multi-layer structure of claim 1, wherein said high thermal deformation layer comprises a polymer selected from the group consisting of: polyamide 6 (PA6), PA 6,6, PA 11, PA 12, polyamide alloys, polycarbonate, polyethylene terephthalate (PET), polyethylene naphthylate (PEN), and polybutylene terephthalate (PBT).

3. The multi-layer structure of claim 2, wherein said high thermal deformation layer is polyethylene terephthalate or polybutylene terephthalate.

4. The multi-layer structure of claim 1, wherein said fluoropolymer is selected from the group consisting of polyvinylidene fluoride (PVDF), ethylene tetrafluoroethylene (ETFE), terpolymers of ethylene with tetrafluoroethylene and hexafluoropropylene (EFEP), terpolymers of tetrafluoroethylene-hexafluoropropylene-vinyl fluoride (THV), blends of PVDF with polymethyl methacrylate polymers and copolymers, ethylene chlorotrifluoroethylene (ECTFE) and polyvinyl fluoride (PVF).

5. The multi-layer structure of claim 4, wherein said fluoropolymer comprises a PVDF homopolymer or copolymer.

6. The multi-layer structure of claim 1, wherein said fluoropolymer film is a multi-layer fluoropolymer film.

7. The multi-layer structure of claim 1, wherein said UV opaque fluoropolymer film comprises 2.0 percent to 30 percent by weight, of at least one white pigment, based on the polymer.

8. The multi-layer structure of claim 7, wherein said white pigment comprises titanium dioxide.

9. The multi-layer structure of claim 1, wherein said UV opaque fluoropolymer film comprises 0.05 to 5 weight percent of UV absorber, nanopigments, or a mixture thereof.

10. The multi-layer structure of claim 1, wherein said structure is a 5 layer structure, consisting of, in order: a first UV opaque fluoropolymer film layer, said adhesive composition layer, a high thermal deformation temperature layer, said adhesive composition layer, and a second UV opaque fluoropolymer film layer, wherein said first and second UV opaque fluoropolymer film layers can be the same or different.

11. The multi-layer structure of claim I, wherein said adhesive composition comprises
a) 5-80 weight percent of one or more aliphatic urethane acrylates formed from an aliphatic urethane acrylate oligomer, mono or multifunctional (meth)acrylate oligomers having polyesters and/or epoxy backbones; or aromatic oligomers; and
b) 95 to 20 weight percent of mono and multifunctional (meth)acryl ate monomers; mono or multifunctional (meth)acrylate oligomers having polyesters and/or epoxy backbones; or aromatic oligomers.

12. The multi-layer structure of claim 11, wherein said aliphatic urethane acrylates are based on polyester and/or polycarbonate polyols,

13. The multi-layer structure of claim 1, wherein said adhesive composition comprises at least one photoinitiator selected from the group consisting of his acyl phosphine oxide (BAPO), and trimethyl-diphenyl-phosphineoxide (TPO), and mixtures thereof.

14. A method for adhering a UV opaque fluoropolymer film to a high thermal deformation temperature substrate, comprising the steps of;
a) forming a UV curable adhesive composition comprising:
1) an adhesive comprising an aliphatic urethane acrylate oligomer, and one or more (meth)acrylate monomers, and
2) a photoinitiator;
b) applying said adhesive composition between a high thermal deformation temperature layer and at least one UV opaque fluoropolymer layer;
c) laminating together said high thermal deformation temperature layer, at least one UV opaque fluoropolymer layer, and said adhesive composition to form a multi-layer structure;
d) exposing said coated and laminated multilayer structure to long UV (>400 nm) wavelength radiation, or e-beam radiation, to produce a cured adhesive layer directly bonding said high thermal deformation temperature layer to said fluoropolymer film(s).

15. The method of claim 14, wherein said fluoropolymer film comprises a polyvinylidene fluoride homopolymer or copolymer.

16. The method of claim 14, wherein said pigmented fluoropolymer comprises 2.0 percent to 30 percent by weight, of at least one white pigment, based on the polymer.

17. The method of claim 14, wherein said high thermal deformation layer comprises a polymer selected from the group consisting of: polyamide 6 (PA6), PA 6,6, PA 11, PA 12, polyamide alloys, polyethylene terephthalate (PET), polyethylene naphthylate (PEN), and polybutylene terephthalate (PBT).

18. The method of claim 16, wherein said white pigment comprises titanium dioxide.

19. The method of claim 14, wherein in said radiation curable adhesive composition, said adhesive is selected from the group consisting of an aliphatic urethane acrylate formed from an aliphatic urethane acrylate oligomer in combination with one or more moieties selected from the group consisting of monofunctional (meth)acrylate monomers, multifunctional (meth)acrylate monomers, monofunctional (meth)acrylate oligomers having polyesters and/or epoxy backbones, multifunctional (meth)acrylate oligomers having polyesters and/or epoxy backbones; and said photoinitiator is selected from bis acyl phosphine oxide (BAPO), and trimethyl-diphenyl-phosphineoxide (TPO).

20. A photovoltaic module comprising, on the back side, facing away from direct solar radiation, a backsheet comprising the multi-layer structure of claim 1.

21. A photovoltaic module comprising on the back side, facing away from direct solar radiation, a backsheet comprising a multi-layer structure comprising:
a) a high thermal deformation temperature layer;
b) an adhesive composition layer cured fully or partially by UV, LED or e-beam radiation;
c) a UV transparent fluoropolymer film layer;
wherein the layers are adjacent to each other.

22. The photovoltaic module of claim 21, wherein said adhesive composition, or said high thermal deformation temperature layer is UV opaque.
